(19) United States
(12) Patent Application Publication
(10) Pub. No.: US 2015/0109672 A1
(43) Pub. Date: Apr. 23, 2015

(54) Reflective Diffraction Grating and Method for the Production Thereof

(71) Applicant: Fraunhofer-Gesellschaft zur Förderung der angewandten Forschung c.V., Munich (DE)

(72) Inventors: Frank Fuchs, Jena (DE); Uwe D. Zeitner, Weimar (DE)

(21) Appl. No.: 14/395,424

(22) PCT Filed: Apr. 16, 2013
(86) PCT No.: PCT/EP2013/057924

§ 371 Date: Oct. 17, 2014

(30) Foreign Application Priority Data
Apr. 19, 2012 (DE) 10 2012 103 443.5

(51) Int. Cl. G02B 5/18; G03F 7/20; C23C 16/455

(52) U.S. Cl. CPC G02B 5/1861; G02B 5/1857; C23C 16/45525; G03F 7/2037
USPC 359/572; 427/162; 430/296

(57) ABSTRACT

A reflective diffraction grating includes a substrate and a reflection-enhancing interference layer system. The reflection-enhancing interference layer system has alternating low refractive index dielectric layers having a refractive index n1 and high refractive index dielectric layers having a refractive index n2>n1. The reflective diffraction grating also includes a grating containing a grating structure, which is formed in the topmost low refractive index layer on a side of the interference layer system facing away from the substrate, and a cover layer, which conformally covers the grating structure. The cover layer has a refractive index n3>n1.

This patent application is a national phase filing under section 371 of PCT/EP2013/057924, filed April 16, 2013, which claims the priority of German patent application 10 2012 103 443.5, filed Apr. 19, 2012, each of which is incorporated herein by reference in its entirety.

### TECHNICAL FIELD

The invention relates to a reflective diffraction grating and to a method for the production thereof.

### BACKGROUND

Reflective diffraction gratings can be realized by a surface grating structure on a reflector. Metal layers and dielectric interference layer systems are suitable as reflectors. Dielectric interference layer systems typically have a multiplicity of alternating low refractive index and high refractive index layers. When a dielectric interference layer system is used as a reflector, the grating structure is generally formed as a surface grating in a topmost layer of the interference layer system facing away from the substrate.

For some applications it proves to be advantageous to realize the grating structure in a high refractive index layer of the interference layer system. In particular, the spectral bandwidth and/or the diffraction efficiency for a desired order of diffraction can be increased in this way. However, it proves to be difficult to apply known dry etching methods such as reactive ion etching or reactive ion beam etching to specific high refractive index materials, since the latter cannot be structured or can be structured only poorly by means of such etching methods. The etching processes used for structuring diffraction gratings having periods of typically <1 μm generally require an optimization specific to the material and the structure of the grating. Primarily the homogeneity of the etching process and the profile fidelity in comparison with the design of the grating structure prove to be problematic here. As the number of material options increases, the optimization complexity increases to a corresponding extent. Furthermore, there are interactions between different etching processes in some instances, with the result that etching installations in some instances can be operated only for individual materials and etching process combinations.

### SUMMARY

Embodiments of the invention specify a reflective diffraction grating which is distinguished by a high diffraction efficiency and a high spectral bandwidth. Further embodiments of the invention specify a method for producing the reflective diffraction grating by which the reflective diffraction grating can be produced in a comparatively simple manner.

In accordance with at least one configuration, the reflective diffraction grating comprises a substrate, to which a reflection-enhancing interference layer system is applied. The reflection-enhancing interference layer system has alternating low refractive index dielectric layers having a refractive index n1 and high refractive index dielectric layers having a refractive index n2>n1. The terms “low refractive index” and “high refractive index” should be understood in each case relative to the refractive index of the other layer type of the alternating layers. Low refractive index layers are understood to mean, in particular, such layers which have a refractive index n1<1.6. High refractive index layers are understood to mean, in particular, such layers which have a refractive index n2>1.6, preferably n2>2.0.

The reflection-enhancing interference layer system comprises for example at least five, preferably at least ten alternating high refractive index and low refractive index layers.

The reflective diffraction grating furthermore comprises a grating having a grating structure, which is formed in the topmost low refractive index layer on a side of the reflection-enhancing interference layer system facing away from the substrate, and a cover layer, which conformally covers the grating structure. The cover layer has a refractive index n3>n1.

By virtue of the fact that the grating structure is formed in the topmost low refractive index layer of the interference layer system, it is possible to dispense with a generally difficult optimization of the etching process for a high refractive index material. In order to obtain a high bandwidth and high diffraction efficiency of the reflective diffraction grating despite the grating structure being formed in the low refractive index layer of the interference layer system, the grating structure produced in the low refractive index layer is conformally covered with a layer having a higher refractive index n3>n1. In this context, “conformally covered” means that the cover layer reproduces the structure of the grating structure and thus forms a grating having an identical grating constant. In particular, the cover layer is not so thick that it planarizes the underlying grating structure. Such a conformal covering of the grating structure in the low refractive index layer with the material of the cover layer can be realized in particular by atomic layer deposition (ALD). Alternatively, chemical vapor deposition (CVD), for example, can be used for producing the cover layer.

The material of the cover layer is preferably a high refractive index material having a refractive index n3>1.6, preferably n3>2.0. Since the high refractive index material of the cover layer is applied by means of a coating method, structuring by means of an etching process is advantageously not necessary.

The grating structure produced in the topmost low refractive index layer and the cover layer which conformally covers the grating structure form a surface grating on the reflection-enhancing interference layer system. The optimization of the grating structure and of the thickness of the cover layer is preferably carried out with the aid of rigorous methods such as, for example, RCWA (Rigorous Coupled Wave Analysis).

The cover layer on the grating structure is preferably a dielectric layer. In one preferred configuration, the cover layer is formed from the same material as the high refractive index layers of the interference layer system.

In one preferred configuration, the refractive index n3 of the cover layer is greater than the refractive index n1 of the low refractive index layers by at least 0.4. In this way, as a result of the cover layer being applied to the topmost low refractive index layer, the diffraction efficiency can be significantly increased.

In order to obtain a particularly high reflection with the reflection-enhancing interference layer system, the refractive index n2 of the high refractive index layers is greater than the refractive index n1 of the low refractive index layers by at least 0.4.

The low refractive index layers preferably comprise a silicon oxide, in particular silicon dioxide. Silicon dioxide can advantageously be structured by means of etching processes known per se. This results in a comparatively low production complexity.

The high refractive index layers of the interference layer system preferably contain titanium dioxide, tantalum pentoxide or hafnium oxide. These materials advantageously have a comparatively high refractive index, thus resulting in an advantageously high refractive index contrast with respect to a low refractive index dielectric material such as silicon dioxide, for example.

In one preferred configuration, the cover layer contains titanium dioxide, tantalum pentoxide or hafnium dioxide. In particular, the same high refractive index materials as for the high refractive index layers of the interference layer system are suitable for the cover layer.

The cover layer preferably has a thickness of between 10 nm and 150 nm. The grating comprising the grating structure in the topmost low refractive index layer and the cover layer advantageously has a thickness of between 20 nm and 1000 nm. The period length of the grating is advantageously less than 5 μm, preferably less than 1 μm.

The method for producing the reflective diffraction grating involves firstly providing a substrate and then depositing the reflection-enhancing interference layer system having alternating low refractive index dielectric layers having a refractive index n1 and high refractive index dielectric layers having a refractive index n2>n1. The reflection-enhancing interference layer system can be deposited by means of coating methods known per se, in particular by means of PVD or CVD methods such as, for example, thermal evaporation, electron beam evaporation or sputtering.

During the production of the dielectric interference layer system, a low refractive index layer is applied as the topmost layer. A grating structure is subsequently formed in the low refractive index topmost layer of the dielectric interference layer system. The grating structure is advantageously formed by means of a lithography method, preferably by means of electron beam lithography. By means of the lithography method, the structure is produced in a mask material and subsequently transferred to the material of the topmost low refractive index layer by means of an etching process, for example by means of a dry etching method such as, in particular, reactive ion etching or reactive ion beam etching.

In a further method step, a cover layer having a refractive index entry n3>n1 is applied to the grating structure in such a way that the cover layer conformally covers the grating structure. In order to achieve this, the cover layer is preferably applied by means of atomic layer deposition (ALD).

Alternatively, however, other coating methods such as, for example, chemical vapor deposition (CVD) can also be used for applying the cover layer.

Further advantageous configurations of the method are evident from the previous description of the reflective diffraction grating, and vice versa.

### BRIEF DESCRIPION OF DRAWINGS

The invention is explained in greater detail below on the basis of exemplary embodiments in association with FIGS. 1 to 3.

In the figures:

FIG. 1 shows a schematic illustration of a cross section through one exemplary embodiment of the reflective diffraction grating in an intermediate step of the production method;

FIG. 2 shows a schematic illustration of a cross section through one exemplary embodiment of the reflective diffraction grating; and

FIG. 3 shows a graphical illustration of the diffraction efficiency as a function of the wavelength X for one exemplary embodiment of the reflective diffraction grating.

Identical or identically acting component parts are provided with the same reference signs in each case in the figures. The illustrated component parts and the size relationships of the component parts among one another should not be regarded as true to scale.

### DETAILED DESCRIPTION OF ILLUSTRATIVE EMBODIMENTS

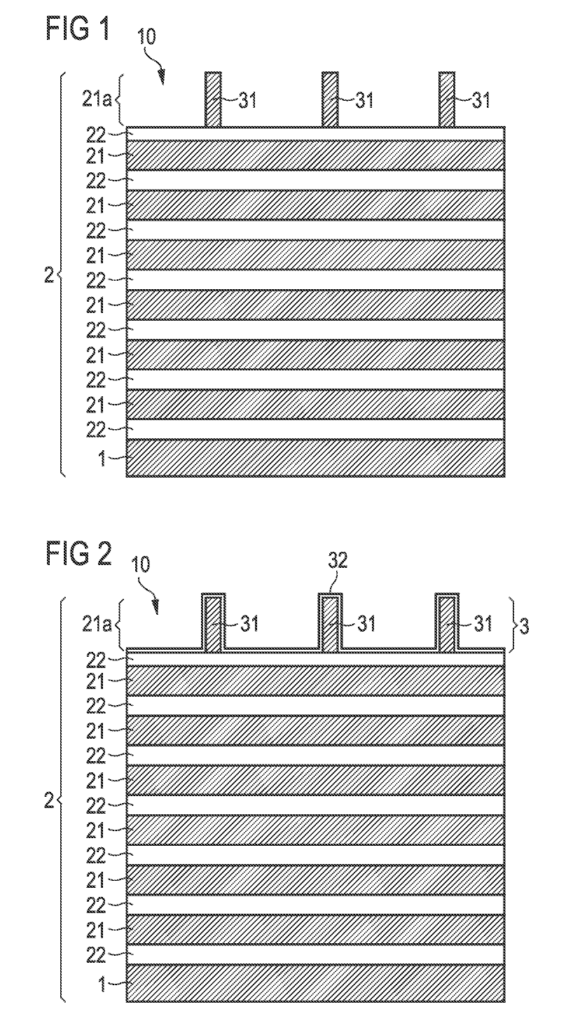

FIG. 1 illustrates the not yet completed reflective diffraction grating 10 in an intermediate step of the production method. In the intermediate step illustrated, a reflection-enhancing dielectric interference layer system 2 having a plurality of alternating low refractive index layers 21 and high refractive index layers 22 has already been applied to a substrate 1.

The substrate 1 of the reflective diffraction grating 10 can comprise fused silica, for example. Alternatively, some other substrate 1, preferably composed of a glass, a glass ceramic or a plastic, could also be used.

The alternating low refractive index layers 21 and high refractive index layers 22 of the dielectric interference layer system 2 can be, in particular, oxides, nitrides or fluorides. The low refractive index layers 21 preferably contain a silicon oxide, in particular silicon dioxide (SiO₂). The high refractive index layers 22 preferably contain tantalum pentoxide (Ta₂O₅), titanium dioxide (TiO₂) or hafnium dioxide (HfO₂).

The low refractive index layers 21 advantageously have a refractive index n1<1.6 and the high refractive index layers 22 a refractive index n2>1.6. In order to obtain a high reflection, it preferably holds true that n2−n1>0.4. In this way, a high refractive index contrast is obtained at the interfaces of the interference layer system 2, as a result of which the reflection of the layer system can be increased.

A grating structure 31 has been produced in the topmost low refractive index layer 21a of the reflection-enhancing interference layer system 2. The grating structure 31 can be implemented for example by means of a lithographic structuring of a mask and subsequent transfer of the structure to the topmost low refractive index layer 21a by means of an etching process. The lithographic structuring can be effected by means of electron beam lithography, in particular.

In this case, it is advantageous that the grating structure is produced in the topmost low refractive index layer 21a of the reflection-enhancing dielectric layer system 2, since a low refractive index layer such as preferably SiO₂ in many cases can be structured more simply than typical high refractive index materials, wherein dry etching methods that are known per se and already optimized can be employed particularly in the case of SiO₂.

It has been found, however, that with a reflective diffraction grating in which the grating structure 31 is produced in the topmost low refractive index layer 21a of a reflection-enhancing interference layer system 2, generally it is possible to achieve only a lower diffraction efficiency and/or spectral bandwidth compared with a reflective diffraction grating comprising a grating structure in a high refractive index layer.

In order largely to compensate for this disadvantage, as can be seen in the exemplary embodiment of a reflective diffraction grating 10 illustrated in FIG. 2, the grating structure 31 is conformally covered with a cover layer 32, wherein the cover layer 32 has a refractive index n3 that is greater than the refractive index n1 of the topmost low refractive index layer 21a. The grating 3 of the reflective diffraction grating 10 is therefore formed by the grating structure 31 with the cover layer 32 applied thereto. The cover layer 32 is advantageously a high refractive index dielectric layer having a refractive index n3>1.6. Preferably, the refractive index n3 of the cover layer 32 is greater than the refractive index n1 of the topmost low refractive index layer 21a by at least 0.4.

In one advantageous configuration, the cover layer 32 has the same refractive index as the high refractive index layers 22 of the reflection-enhancing interference layer system 2, that is to say that n2=n3 holds true. In this case, the dielectric interference layer system 2 and the grating 3 can advantageously be produced from only two materials. However, it is not absolutely necessary for the cover layer 32 to comprise the same material as the high refractive index layers 22 of the reflection-enhancing interference layer system 2. It is also possible for the cover layer 32 and the high refractive index layers 22 to be formed from two different high refractive index materials.

The cover layer 32 covers the grating structure 31 in the topmost low refractive index layer 21a conformally, that is to say that it reproduces the form of the grating structure, with the result that it forms a grating having the same grating constant as the grating structure. In order to conformally cover the grating structure 31 with the cover layer 32, the cover layer 32 is preferably applied by means of atomic layer deposition.

In the design of the reflective diffraction grating 10 for a specific application, so-called rigorous simulation methods, in particular RCWA, can be used. In particular, the parameters of the grating structure 31, the thickness of the applied cover layer 32 and the refractive indices n1 and n3 of the grating structure and of the cover layer are taken into account in this case.

The cover layer 32 preferably has a thickness of between 10 nm and 150 nm. The grating comprising the grating structure 31 in the topmost low refractive index layer 21a and the cover layer 32 advantageously has a thickness of between 20 nm and 1000 nm. The period length of the grating is advantageously less than 5 μm, preferably less than 1 μm.

The reflective grating 10 combines, in particular, the advantages of the good structurability of a low refractive index layer material such as SiO₂, for example, with the advantages of a grating structure comprising a high refractive index material.

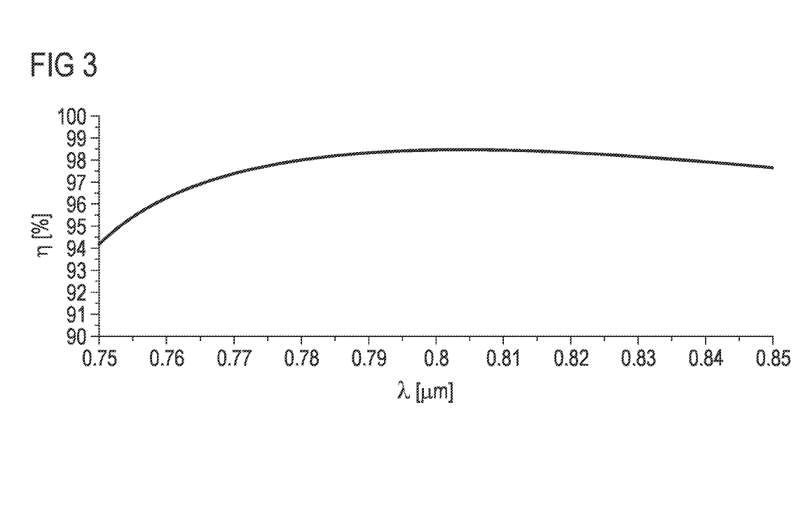

FIG. 3 shows a graphical illustration of the diffraction efficiency η of the −1^{st} order of diffraction for the reflective diffraction grating as illustrated in FIG. 2 as a function of the wavelength λ. The reflective diffraction grating has a grating period of 555 nm. The illustration shows the calculated diffraction efficiency for TE polarization at an angle of incidence of 57° from air. The graph illustrates that the reflective diffraction grating has an advantageously high diffraction efficiency in the illustrated wavelength range of 0.75 μm to 0.85 μm.

The invention is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or exemplary embodiments.

1-15. (canceled)

16. A reflective diffraction grating, comprising:
a substrate;
a reflection-enhancing interference layer system, which has alternating low refractive index dielectric layers having a refractive index n1 and high refractive index dielectric layers having a refractive index n2, where n2>n1; and
a grating, comprising a grating structure, which is formed in a topmost low refractive index layer on a side of the interference layer system facing away from the substrate, and a cover layer, which conformally covers the grating structure, wherein the cover layer has a refractive index n3, where n3>n1.

17. The reflective diffraction grating according to claim 16, wherein n3>1.6.

18. The reflective diffraction grating according to claim 16, wherein the cover layer comprises a dielectric layer.

19. The reflective diffraction grating according to claim 16, wherein the cover layer is formed from the same material as the high refractive index layers of the interference layer system.

20. The reflective diffraction grating according to claim 16, wherein n3−n1>0.4.

21. The reflective diffraction grating according to claim 16, wherein n2−n1>0.4.

22. The reflective diffraction grating according to claim 16, wherein the low refractive index layers comprise silicon dioxide.

23. The reflective diffraction grating according to claim 16, wherein the high refractive index layers comprise titanium dioxide, tantalum pentoxide or hafnium dioxide.

24. The reflective diffraction grating according to claim 23, wherein the cover layer is formed from the same material as the high refractive index layers of the interference layer system.

25. The reflective diffraction grating according to claim 16, wherein the low refractive index layers comprise silicon dioxide and wherein the high refractive index layers comprise titanium dioxide, tantalum pentoxide or hafnium dioxide.

26. The reflective diffraction grating according to claim 16, wherein the cover layer comprises titanium dioxide, tantalum pentoxide or hafnium dioxide.

27. The reflective diffraction grating according to claim 16, wherein the cover layer has a thickness of between 10 nm and 150 nm.

28. The reflective diffraction grating according to claim 16, wherein the grating has a thickness of between 20 nm and 1000 nm.

29. The reflective diffraction grating according to claim 16, wherein the grating has a period length of less than 5 μm.

30. A method for producing a reflective diffraction grating, the method comprising:
depositing a reflection-enhancing interference layer system over a substrate, reflection-enhancing interference layer system having alternating low refractive index dielectric layers having a refractive index n1 and high refractive index dielectric layers having a refractive index n2>n1;
forming a grating structure in a topmost low refractive index layer of the interference layer system; and
applying a cover layer to the grating structure in such a way that the cover layer conformally covers the grating structure.

31. The method according to claim 30, wherein the cover layer is applied to the grating structure using anatomic layer deposition (ALD) process.

32. The method according to claim 30, wherein the grating structure is produced using an electron beam lithography process.
